(19) United States
(12) Patent Application Publication
(10) Pub. No.: US 2026/0202821 A1
(43) Pub. Date: Jul. 16, 2026

(54) PROCESS SYSTEM PROCESSING WAFER WITH ESTIMATING DEFECT RISK AND OPERATION METHOD THEREOF, AND OPERATION METHOD OF CORRELATION ANALYSIS SYSTEM FOR STRUCTURAL PARAMETERS OF PHYSICAL STRUCTURE FORMED ON WAFER

(71) Applicant: SAMSUNG ELECTRONICS CO., LTD., Suwon-si (KR)

(72) Inventors: MINSEOK KIM, Suwon-si (KR); HYUNGKEUN YOO, Suwon-si (KR); TAESIN KWAG, Suwon-si (KR); YEONJEONG KIM, Suwon-si (KR); SHINYI YANG, Suwon-si (KR); KYUNG HOON LEE, Suwon-si (KR); WOOBOK LEE, Suwon-si (KR); SUNGHOON CHOI, Suwon-si (KR); YOUNGHOON SOHN, Suwon-si (KR); YONG DEOK JEONG, Suwon-si (KR)

(73) Assignee: SAMSUNG ELECTRONICS CO., LTD., Suwon-si (KR)

(21) Appl. No.: 19/296,188

(22) Filed: Aug. 11, 2025

(30) Foreign Application Priority Data
Jan. 16, 2025 (KR) 10-2025-0006921

(51) Int. Cl. G05B 19/4097

(52) U.S. Cl. CPC G05B 19/4097; G05B 2219/40091; G05B 2219/45031

(57) ABSTRACT

A process system according to an embodiment may include a plurality of process equipments configured to process a wafer based on a plurality of process variables, a structural parameter estimation circuit configured to generate, based on a first plurality of actually measured correlated parameter values which are provided from the plurality of process equipments and corresponding to a first target structural parameter of the wafer, a first estimated target structural parameter value for the first target structural parameter, and a process equipment control device configured to control at least one process variable among the plurality of process variables based on the first estimated target structural parameter value.

### CROSS-REFERENCE TO RELATED APPLICATION

This application is based on and claims priority to Korean Patent Application No. 10-2025-0006921, filed on Jan. 16, 2025 with the Korean Patent Office, the disclosure of which is herein incorporated by reference in its entirety.

### BACKGROUND

### 1. Field

The present disclosure relates to a semiconductor process. More specifically, the present disclosure relates to a process system for estimating a defect risk while processing a wafer and an operation method thereof, and an operation method of a correlation analysis system for structural parameters of a physical structure formed on the wafer.

### 2. Description of Related Art

As semiconductors have become increasingly miniaturized, a probability of unexpected structural defects occurring in physical structures formed on a wafer is gradually increasing. These structural defects have a significant impact on a quality and performance of semiconductor devices.

However, some types of structural defects are difficult to identify while process stages proceed. For example, some structural defects can only be tested, by destructive testing methods such as transmission electron microscopy (TEM) analysis, after many process stages have been completed.

### SUMMARY

The present disclosure is intended to solve the technical problems described above. More specifically, the present disclosure attempts to provide a process system configured to identify whether a structural defect difficult to identify occurs while process stages are in progress and an operation method thereof, and an operation method of a correlation analysis system configured to generate a structural parameter estimation function representing a correlation between structural parameters of a physical structure formed on a wafer.

According to an aspect of an example embodiment of the present disclosure, provided is a process system according to an embodiment of the present disclosure including: a plurality of process equipments configured to process a wafer based on a plurality of process variables; a structural parameter estimation circuit configured to generate, based on a first plurality of actually measured correlated parameter values which are provided from the plurality of process equipments and corresponding to a first target structural parameter of the wafer, a first estimated target structural parameter value for the first target structural parameter; and a process equipment control device configured to control at least one process variable among the plurality of process variables based on the first estimated target structural parameter value.

According to an aspect of an example embodiment of the present disclosure, provided is an operation method of correlation analysis system including: generating a plurality of simulation data for a physical structure formed on a wafer; generating, for each of the plurality of simulation data, a virtually measured target structural parameter value corresponding to a target structural parameter for the physical structure; generating, for each of the plurality of simulation data, a combination of virtually measured correlated parameter values including a plurality of virtually measured correlated parameter values respectively corresponding to a plurality of correlated structural parameters for the target structural parameter; and generating a structural parameter estimation function based on the combination of the virtually measured correlated parameter values and virtually measured target structural parameter values, corresponding to each of the plurality of simulation data.

According to an aspect of an example embodiment of the present disclosure, provided is an operation method of a process system processing a wafer including: storing a structural parameter estimation function corresponding to a target structural parameter and a plurality of correlated structural parameters of a physical structure formed on the wafer; generating a plurality of actually measured correlated parameter values respectively corresponding to a plurality of correlated structural parameters, during a plurality of process stages for the wafer; generating an estimated target structural parameter value for the target structural parameter by substituting the plurality of actually measured correlated parameter values into the structural parameter estimation function; and adjusting a plurality of process variables provided to a plurality of process equipments based on the estimated target structural parameter value.

### BRIEF DESCRIPTION OF DRAWINGS

The above and other aspects and features of the present disclosure will become more apparent by describing in detail example embodiments thereof with reference to the attached drawings:

FIG. 1 is a block diagram showing a process system according to an embodiment of the present disclosure.

FIG. 2 is a diagram showing an example of classification of structural parameters according to an embodiment of the present disclosure.

FIG. 3 is a drawing showing an example of a part of a physical structure explained with FIG. 1.

FIG. 4 is a block diagram showing a configuration of correlation analysis system according to an embodiment of the present disclosure.

FIG. 5 is a diagram showing a relationship between a process variable combination and a combination of virtually measured correlated parameter values according to an embodiment of the present disclosure.

FIG. 6 is a diagram showing an operation of a structural parameter estimation function generation module of FIG. 4.

FIG. 7 is a flowchart showing an operation of a correlation analysis system and a process system according to an embodiment of the present disclosure.

FIG. 8 is a flowchart showing operation S100 of FIG. 7 according to an embodiment of the present disclosure.

FIG. 9 is a flowchart showing operation S200 of FIG. 7 according to an embodiment of the present disclosure.

FIG. 10 is a block diagram showing a configuration of a correlation analysis system according to an embodiment.

FIG. 11 is a diagram showing an operation of a correlated structural parameter filtering module of FIG. 10 according to an embodiment of the present disclosure.

FIG. 12 is a flowchart showing operation S140 of FIG. 8 in more detail according to the embodiments of FIGS. 10 and 11.

FIG. 13 is a block diagram showing a configuration of a process system according to an embodiment.

FIG. 14 is a block diagram showing a configuration of a process system according to an embodiment.

FIG. 15 is a diagram showing an operation of another process system in an embodiment.

FIG. 16 is a drawing showing a configuration of a wafer of FIG. 1 according to an embodiment.

### DETAILED DESCRIPTION

Hereinafter, various example embodiments will be described in detail and clearly to such an extent that one of ordinary skill in the art easily implements the present disclosure. Specific details such as detailed components and structures are merely provided to assist the overall understanding of the various embodiments. Therefore, it should be apparent to those skilled in the art that various changes and modifications of the embodiments described herein may be made without departing from the scope and spirit of the present disclosure. Moreover, descriptions of well-known functions and structures are omitted for clarity and brevity. In the following drawings or in the detailed description, configurations may be connected with any other components except for components illustrated in a drawing or described in the detailed description. The terms described below are terms defined in consideration of the functions of the present disclosure and are not limited to a specific function. The definitions of the terms should be determined based on the contents throughout the specification.

Components that are described in the detailed description with reference to the terms “driver”, “block”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, a microelectromechanical system (MEMS), a passive element, or any combination thereof.

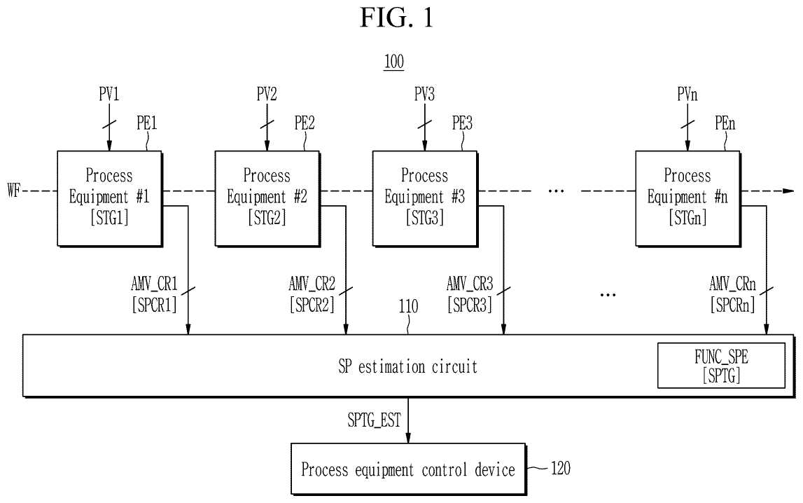

FIG. 1 is a block diagram showing a process system according to an embodiment of the present disclosure. Referring to FIG. 1, a process system 100 may include a plurality of process equipments PE. For example, the process system 100 may include first to n-th process equipments PE1 to PEn.

Each of the first to n-th process equipments PE1 to PEn may process a wafer WF by performing same or different types of process stages. For example, the first to n-th process equipments PE1 to PEn may form a specific physical structure (hereinafter referred to as “PHY”) on the wafer WF by performing first to n-th process stages STG1 to STGn, respectively.

The first to n-th process stages STG1 to STGn may be same or different from each other. For example, each of the first to n-th process stages STG1 to STGn may be one of various types of semiconductor process stages, such as an oxidation stage, a photolithography stage, an etching stage, an ion implantation stage, a deposition stage, a metallization stage, and the like. However, the scope of the present disclosure is not limited to specific types of each of the first to n-th process stages STG1 to STGn.

The first to n-th process equipments PE1 to PEn may operate based on first to n-th process variables PV1 to PVn, respectively. For example, the first process facility PE1 may perform the first process stage STG1 based on the first process variable PV1.

For concise explanation, hereinafter, an embodiment is representatively described in which each of the first to n-th process equipments PE1 to PEn operates based on one process variable, but the scope of the present disclosure is not limited thereto. For example, some of the first to n-th process equipments PE1 to PEn may operate based on two or more process variables. For example, if the first process stage STG1 is a photolithography stage, the first process equipment PE1 may perform the first process stage STG1 based on various process variables such as a wavelength of light, an exposure time, and the like; if the second process stage STG2 is an etching stage, the second process equipment PE2 may perform the second process stage STG2 based on various process variables such as a concentration of an etchant, an etching type (e.g., wet etching, dry etching, and the like). That is, the scope of the present disclosure is not limited to a number and types of process variables required by each of the first to n-th process equipments PE1 to PEn.

In an embodiment, each of the first to n-th process stages STG1 to STGn may be performed sequentially. However, the scope of the present disclosure is not limited thereto, and some of the first to n-th process stages STG1 to STGn may be performed simultaneously.

In an embodiment, some of the first to n-th process stages STG1 to STGn may be process stages of same type. In this case, some of the first to n-th process equipments PE1 to PEn may be implemented with a process equipment. However, the scope of the present disclosure is not limited thereto.

In an embodiment, the process system 100 may further include a process equipment that performs process stages other than the first to n-th process stages STG1 to STGn. For example, the process system 100 may perform one or more process stages, which are different from the first to n-th process stages, before the first process stage STG1 or after the n-th process stage STGn. However, the scope of the present disclosure is not limited thereto, and one or more other process stages may be further included between the first to n-th process stages STG1 to STGn. In other words, the scope of the present disclosure is not limited to whether the first to n-th process stages STG1 to STGn are continuous with each other.

The first to n-th process equipments PE1 to PEn may form a specific physical structure PHY on the wafer WF by performing the first to n-th process stages STG1 to STGn. In this case, whether a structural defect occurs on the physical structure PHY (or whether a structural defect occurs in a semiconductor device manufactured based on the wafer WF) may be determined depending on whether the physical structure PHY is formed as intended on the wafer WF.

Whether the physical structure PHY is formed as intended may be determined based on values of various types of structural parameters SP defined for the physical structure PHY. For example, whether the physical structure PHY is formed as intended may be determined based on whether the values of structural parameters SP, such as a spacing between two points (e.g., spots) on the physical structure PHY, are within a specific range.

Some structural parameters SP defined for the physical structure PHY may be difficult to measure while the first to n-th process stages STG1 to STGn are being performed. For example, some structural parameters SPs can only be tested by using a destructive testing scheme such as transmission electron microscopy (TEM) analysis. In this case, it may be difficult to predict whether a structural defect corresponding to the structural parameters SP will occur while the first to n-th process stages STG1 to STGn proceed. Therefore, it may result in excessive cost and time required for manufacturing semiconductor devices based on the physical structures PHY on the wafer WF, and it may result in reduction of production yields of semiconductor devices.

The process system 100 according to an embodiment of the present disclosure may include a structural parameter estimation circuit 110 and a process equipment control device 120.

The structural parameter estimation circuit 110 may estimate a specific structural parameter SP defined for a physical structure PHY (hereinafter, the specific structural parameter SP may be referred to as a target structural parameter SPTG). The structural parameter estimation circuit 110 may store a structural parameter estimation function FUNC_SPE. The structural parameter estimation circuit 110 may estimate a size of the target structural parameter SPTG, which is difficult to directly measure while the first to n-th process stages STG1 to STGn proceed, based on the structural parameter estimation function FUNC_SPE. The size of the estimated target structural parameter SPTG may be referred to as an estimated target structural parameter value SPTG_EST.

More specifically, the first to n-th process equipments PE1 to PEn may actually measure sizes of first to n-th correlated structural parameters SPCR1 to SPCRn that are correlated with the target structural parameters SPTG, respectively. For example, each of the first to n-th process equipments PE1 to PEn may directly measure a size of the correlated structural parameter SPCR based on various methods such as optical metrology, electron beam metrology, atomic force microscopy, and X-ray metrology. The sizes of the first to n-th actually measured correlated structural parameters SPCR1 to SPCRn may be referred to as first to n-th actually measured correlated parameter values AMV_CR1 to AMV_CRn, respectively.

For brevity, hereinafter, an embodiment in which each of the first to n-th process equipments PE1 to PEn measures a size of one correlated structural parameter SPCR will be described representatively, but the scope of the present disclosure is not limited thereto. For example, some of the first to n-th process equipments PE1 to PEn may measure two or more correlated structural parameters SPCR. For example, if the first process stage STG1 is a photolithography stage, the first process equipment PE1 may be capable of measuring a depth and a width of a pattern formed by photolithography. That is, the scope of the present disclosure is not limited to a number and a type of actually measured correlated parameter values AMV_CR provided by each of the first to n-th process equipments PE1 to PEn to the structural parameter estimation circuit 110.

In an embodiment, a number of actually measured correlated parameter values generated by each of the first to n-th process equipments PE1 to PEn may be limited. That is, the number of structural parameters SP measured by each of the first to n-th process equipments PE1 to PEn may be controlled by the process equipment control device 120. The process equipment control device 120 may control the first to n-th process equipments PE1 to PEn to measure structural parameters (e.g., correlated structural parameters SPCR) that are correlated with the target structural parameter SPTG.

The structural parameter estimation circuit 110 may receive actually measured values for the structural parameters SP correlated with target structural parameters SPTG from each of the first to n-th process equipments PE1 to PEn. For example, the structural parameter estimation circuit 110 may receive the first to n-th actually measured correlated parameter values AMV_CR1 to AMV_CRn.

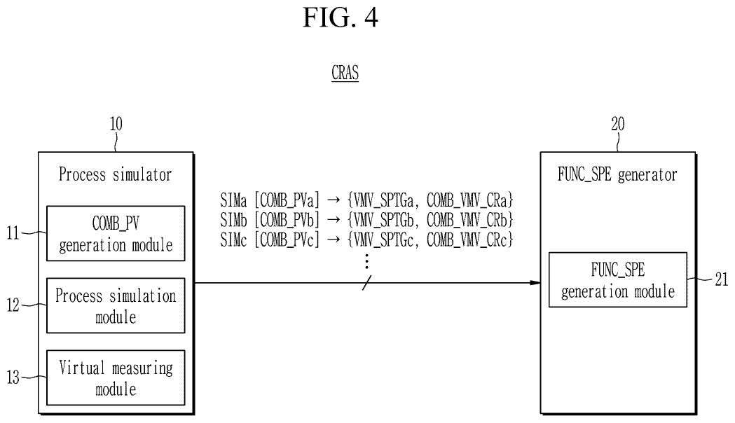

The structural parameter estimation circuit 110 may estimate the size of the target structural parameter SPTG based on the first to n-th actually measured correlated parameter values AMV_CR1 to AMV_CRn and the structural parameter estimation function FUNC_SPE. For example, the structural parameter estimation circuit 110 may calculate the estimated target structural parameter value SPTG_EST by substituting the first to n-th actually measured correlated parameter values AMV_CR1 to AMV_CRn into the structural parameter estimation function FUNC_SPE. For example, the structural parameter estimation function FUNC_SPE may be a linear function for each of the plurality of actually measured correlated parameter values. Examples of a configuration of the structural parameter estimation function FUNC_SPE and a method of generating the structural parameter estimation function FUNC_SPE according to embodiments will be described in more detail with reference to FIGS. 4 to 6 below.

The structural parameter estimation circuit 110 may provide the estimated target structural parameter value SPTG_EST to the process equipment control device 120. The process equipment control device 120 may control the process equipment PE based on the estimated target structural parameter value SPTG_EST. For example, the process equipment control device 120 may identify that there is a high possibility (e.g., defect risk) of a structural defect occurring in a physical structure PHY formed on the wafer WF based on the estimated target structural parameter value SPTG_EST. In this case, the process equipment control device 120 may adjust process variables related to the target structural parameter SPTG among the plurality of process variables PV. Therefore, according to an embodiment of the present disclosure, a possibility of a structural defect occurring when the plurality of process equipments PEs process another wafer WF may be reduced.

That is, according to the embodiment of the present disclosure, the possibility of a structural defect occurring in the physical structure PHY may be reduced. Therefore, according to the embodiments of the present disclosure, manufacturing time and manufacturing cost of a semiconductor device may be reduced, and a production yield may be improved.

In addition, according to an embodiment of the present disclosure, since a structural defect corresponding to the target structural parameter SPTG may be predicted even during the first to n-th process stages STG1 to STGn, the time required for optimizing the plurality of process equipments PEs (e.g., setup a plurality of process variables PVs with appropriate values) may be reduced. Therefore, according to the embodiments of the present disclosure, the development cost and development time of a semiconductor device may be reduced.

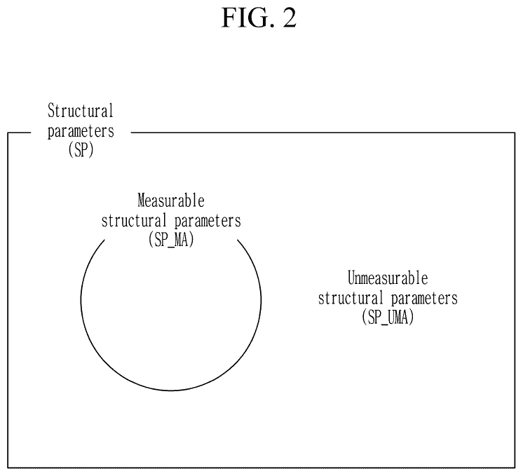

FIG. 2 is a diagram showing an example of classification of structural parameters according to an embodiment of the present disclosure. Referring to FIGS. 1 and 2, each of the structural parameters SP defined for a physical structure PHY formed on the wafer WF may be classified into a measurable structural parameter SP_MA for the plurality of process stages STG or an unmeasurable structural parameter SP_UMA for the plurality of process stages STG.

The measurable structural parameter SP_MA for the plurality of process stages STG may refer to a type of a structural parameter SP that can be measured while the plurality of process stages STG are being performed. For example, the measurable structural parameter SP_MA may refer to a structural parameter SP that can be measured based on the first to n-th process equipments PE1 to PEn. For example, each of the first to n-th correlated structural parameters SPCR1 to SPCRn may be the measurable structural parameter SP_MA for the plurality of process stages STG.

On the other hand, the unmeasurable structural parameter SP_UMA for the plurality of process stages STG may refer to a type of a structural parameter SP that cannot be measured while the plurality of process stages STG are being performed. For example, the unmeasurable structural parameter SP_UMA may refer to a structural parameter SP that cannot be measured based on the first to n-th process equipments PE1 to PEn and only can be measured by the destructive test scheme.

The target structural parameter SPTG may be an unmeasurable structural parameter SP_UMA for the plurality of process stages STG. That is, since the target structural parameter SPTG cannot be measured while the first to n-th process stages STG1 to STGn are being performed, it is difficult to identify a structural defect corresponding to the target structural parameter SPTG while the first to n-th process stages STG1 to STGn are being performed. However, according to an embodiment of the present disclosure, the size of the target structural parameter SPTG may be estimated based on a plurality of measurable structural parameters SP_MA (e.g., the first to n-th correlated structural parameters SPCR1 to SPCRn). Therefore, according to an embodiment of the present disclosure, it may be possible to estimate the possibility that the structural defect corresponding to the target structural parameter SPTG may occur even while the first to n-th process stages STG1 to STGn are being performed.

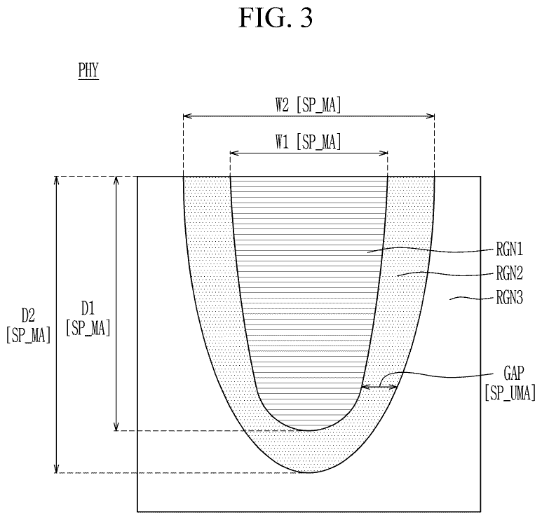

FIG. 3 is a drawing showing an example of a part of the physical structure explained with FIG. 1. Specifically, FIG. 3 shows a portion of a cross-sectional view of the wafer WF cut in a direction perpendicular to a surface of the wafer WF.

Below, an example of a physical structure PHY formed on the wafer WF are described with reference to FIGS. 1 to 3 to understand the unmeasurable structural parameter SP_UMA. However, the scope of the present disclosure is not limited to the specific physical structure PHY illustrated in FIG. 3.

The physical structure PHY may include first to third physical regions RGN1 to RGN3. The first to third physical regions RGN1 to RGN3 may be formed based on different process stages STGs.

In an embodiment, the first to third physical regions RGN1 to RGN3 may have different chemical compositions.

The second physical region RGN2 may be formed between the first physical region RGN1 and the third physical region RGN3. That is, the second physical region RGN2 may isolate the first physical region RGN1 and the third physical region RGN3. For example, the second physical region RGN2 may be formed such that a minimum gap GAP between the first physical region RGN1 and the third physical region RGN3 is greater than a specific value. However, if the process variables PVs provided to the process equipment PE forming each of the first to third physical regions RGN1 to RGN3 are not properly determined, the minimum gap GAP may become smaller than the specific value. Furthermore, if the minimum gap GAP is less than ‘0’, an unintended physical contact (or, physical effects) may be formed between the first physical region RGN1 and the third physical region RGN3, and this physical contact may cause a defect in an operation of a semiconductor device manufactured based on the wafer WF.

The minimum gap GAP may be difficult to measure when the plurality of process stages STGs are in progress. That is, the minimum gap GAP may be an unmeasurable structural parameter SP_UMA for the plurality of process stages STG.

According to an embodiment of the present disclosure, the structural parameter estimation circuit 110 may estimate the minimum gap GAP. For example, when the minimum gap GAP is the target structural parameter SPTG, the structural parameter estimation circuit 110 may generate the estimated target structural parameter value SPTG_EST corresponding to the minimum gap GAP based on a plurality of measurable structural parameters SP_MA.

For example, a depth of the first physical region RGN1 may be a first depth D1, and a width of the first physical region RGN1 may be a first width W1. A depth of the second physical region RGN2 may be a second depth D2, and a width of the second physical region RGN2 may be a second width W2. Each of the first and second depths D1, D2 and the first and second widths W1, W2 may be measurable structural parameter SP_MA. In this case, the structural parameter estimation circuit 110 may generate an estimated target structural parameter value SPTG_EST corresponding to the minimum gap GAP based on the first and second depths D1, D2 and the first and second widths W1, W2.

For concise explanation, FIG. 3 illustrates the gap between different physical regions RGN as an example of the unmeasurable structural parameter SP_UMA, but the scope of the present disclosure is not limited thereto. For example, the unmeasurable structural parameter SP_UMA may be determined as various types of structural parameters such as some physical length, area, width, volume, etc. Even in this case, the structural parameter estimation circuit 110 may estimate the size of the corresponding unmeasurable structural parameter SP_UMA based on sizes of a plurality of measurable structural parameters SP_MA.

FIG. 4 is a block diagram showing a configuration of correlation analysis system according to an embodiment of the present disclosure. Referring to FIGS. 1 to 4, a correlation analysis system CRAS may include a process simulator 10 and a structural parameter estimation function generator 20. Below, an example of a method how the correlation analysis system CRAS generates the structural parameter estimation function FUNC_SPE, by analyzing the correlation between the target structural parameters SPTG and the correlated structural parameters SPCR described above with reference to FIGS. 1 to 3, will be described.

The process simulator 10 may include a process variable combination generation module 11, a process simulation module 12, and a virtual measuring module 13. In an embodiment, each of the process variable combination generation module 11, the process simulation module 12, and the virtual measuring module 13 may be implemented in software, hardware, or a combination thereof. For example, one or more of the process variable combination generation module 11, the process simulation module 12, and the virtual measuring module 13 may each be implemented with a dedicated circuit. However, the scope of the present disclosure is not limited thereto, and one or more of the process variable combination generation module 11, the process simulation module 12, and the virtual measuring module 13 may be implemented as a software module.

The process variable combination generation module 11 may generate a plurality of process variable combinations COMB_PV. Each of the plurality of process variable combinations COMB_PV may be a different combination of the first to n-th process variables PV1 to PVn. For example, the process variable combination generation module 11 may generate first to third process variable combinations COMB_PVa to COMB_PVc. The first to third process variable combinations COMB_PVa to COMB_PVc may be different from each other.

The process simulation module 12 may generate a plurality of simulation data SIM by simulating the plurality of process stages STG included in the process system 100 based on the plurality of process variable combinations COMB_PV. For example, the process simulation module 12 may generate first simulation data SIMa by simulating the first to n-th process stages STG1 to STGn based on the first process variable combination COMB_PVa; may generate second simulation data SIMb by simulating the first to n-th process stages STG1 to STGn based on the second process variable combination COMB_PVb; and may generate third simulation data SIMc by simulating the first to n-th process stages STG1 to STGn based on the third process variable combination COMB_PVc.

In an embodiment, the process simulation module 12 may be optimized prior to generating the plurality of simulation data SIM based on the plurality of process variable combinations COMB_PV. For example, the process simulator 10 may optimize the process simulation module 12, such that the simulation data SIM generated based on the process simulation module 12 corresponds (e.g., substantially identical) with the physical structure PHY generated based on the first to n-th process equipments PE1 to PEn when the first to n-th process equipments PE1 to PEn and the process simulation module 12 operate based on an identical process variable combination COMB_PV. That is, the correlation analysis system CRAS may set up the process simulation module 12 so as to ensure reliability of simulation data SIM generated by the process simulation module 12.

Each of the plurality of simulation data SIM may refer to a three-dimensional model for a physical structure PHY formed on the wafer WF.

Since each of the plurality of simulation data SIM is generated based on a different process variable combination COMB_PV, the physical structures PHY corresponding to the plurality of simulation data SIM may have different shapes each other. For example, if each of the plurality of simulation data SIM corresponds to the physical structure PHY described above with reference to FIG. 3, the size of the structural parameter SP (e.g., first depth D1, minimum gap GAP, etc.) of each of the plurality of simulation data SIM may be different from each other.

The virtual measuring module 13 may measure the size of the plurality of structural parameters SP for each of the plurality of simulation data SIM. For example, the virtual measuring module 13 may measure (more specifically, virtually measure) a target structural parameter SPTG and a plurality of correlated structural parameters SPCR for each of the plurality of simulation data SIM.

Each of the sizes of the measured target structural parameters SPTG for each of the plurality of simulation data SIM may be referred to as a virtually measured target structural parameter value VMV_SPTG. For example, the virtual measuring module 13 may generate first to third virtually measured target structural parameter values VMV_SPTGa to VMV_SPTGc by measuring a target structural parameters SPTG for each of the first to third simulation data SIMa to SIMc.

Each of the sizes of the measured correlated structural parameters SPOR for each of the plurality of simulation data SIM may be referred to as a virtually measured correlated parameter value VMV_CR. The virtually measured correlated parameter values VMV_CR for each of the plurality of simulation data SIM may be referred to as a combination of virtually measured correlated parameter value COMB_VMV_CR. For example, the virtual measuring module 13 may generate a first combination of virtually measured correlated parameter values COMB_VMV_CRa by measuring a plurality of correlated structural parameters SPCR for the first simulation data SIMa; may generate a second combination of virtually measured correlated parameter values COMB_VMV_CRb by measuring a plurality of correlated structural parameters SPCR for the second simulation data SIMb; and may generate a third combination of virtually measured correlated parameter values COMB_VMV_CRc by measuring a plurality of correlated structural parameters SPCR for the third simulation data SIMc. In this case, each of the first to third combinations of virtually measured correlated parameter values COMB_VMV_CRa to COMB_VMV_CRc may include a plurality of virtually measured correlated parameter values VMV_CR respectively corresponding to the first to n-th correlated structural parameters SPCR1 to SPCRn.

The virtual measuring module 13 may provide virtually measured target structural parameter values VMV_SPTG and a combination of virtually measured correlated parameter values COMB_VMV_CR corresponding to each of a plurality of simulation data SIM, to the structural parameter estimation function generator 20.

The structural parameter estimation function generator 20 may include a structural parameter estimation function generation module 21. The structural parameter estimation function generation module 21 may generate the structural parameter estimation function FUNC_SPE based on virtually measured target structural parameter values VMV_SPTG and a combination of virtually measured correlated parameter values COMB_VMV_CR corresponding to each of the plurality of simulation data SIM. For example, the structural parameter estimation function generation module 21 may generate the structural parameter estimation function FUNC_SPE based on one of various types of regression analysis methods, such as multi-linear regression analysis, polynomial regression analysis, etc. However, for concise explanation, an embodiment in which the structural parameter estimation function generation module 21 generates a structural parameter estimation function FUNC_SPE by performing multi-linear regression analysis based on the virtually measured target structural parameter values VMV_SPTG and the combinations of virtually measured correlated parameter values COMB_VMV_CR corresponding to each of the plurality of simulation data SIM will be described. However, the scope of the present disclosure is not limited thereto.

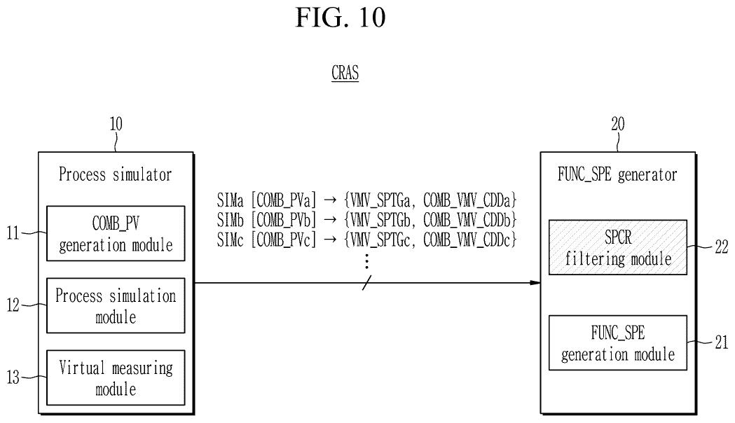

In an embodiment, it may be difficult to identify correlated structural parameters SPCR for a target structural parameter SPTG. For example, it may be difficult to identify which structural parameters SP on the simulation data SIM are the correlated structural parameter SPCR for the target structural parameter SPTG. Accordingly, the virtual measuring module 13 may measure a size of one or more structural parameters that have little or no correlation with the target structural parameter SPTG. In this case, the structural parameter estimation function generator 20 may identify measured values for structural parameters SP highly correlated with the target structural parameter SPTG as the combination of virtually measured correlated parameter values COMB_VMV_CR. An embodiment in which the virtual measuring module 13 measures the size of one or more structural parameters that have little or no correlation with the target structural parameter SPTG will be described in more detail with reference to FIGS. 10 to 12 below.

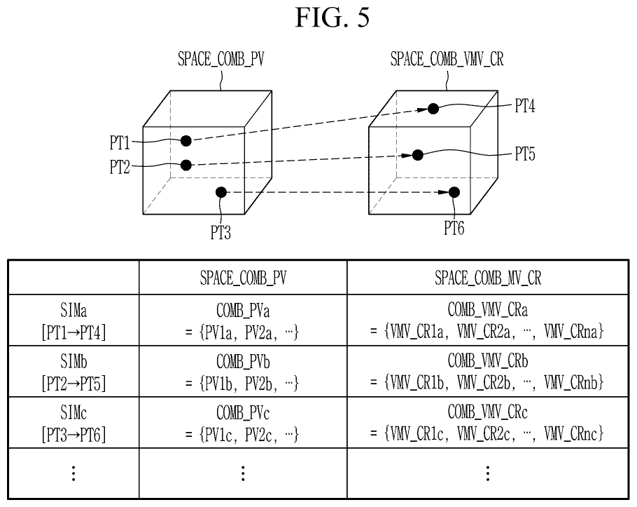

FIG. 5 is a diagram showing relationship between a process variable combination and a combination of virtually measured correlated parameter values corresponding to each of the simulation data in FIG. 4.

Referring to FIGS. 1 to 5, the process variable combination generation module 11 may select a plurality of process variable combinations COMB_PV based on a process variable combination space SPACE_COMB_PV. The process variable combination space SPACE_COMB_PV may be a set of innumerable points PT, which of each corresponds to a different process variable combination COMB_PV. The process variable combination generation module 11 may select a plurality of points PT within the process variable combination space SPACE_COMB_PV and provide process variable combinations COMB_PV corresponding to the selected points PT to the process simulation module 12.

In an embodiment, the process variable combination generation module 11 may randomly select a point PT included in the process variable combination space SPACE_COMB_PV. However, the scope of the present disclosure is not limited thereto.

For example, the process variable combination generation module 11 may provide a first process variable combination COMB_PVa corresponding to a first point PT1 in the process variable combination space SPACE_COMB_PV, a second process variable combination COMB_PVb corresponding to a second point PT2 in the process variable combination space SPACE_COMB_PV, and a third process variable combination COMB_PVc corresponding to a third point PT3 in the process variable combination space SPACE_COMB_PV, to the process simulation module 12.

Each of the plurality of process variable combination COMB_PV may include a plurality of process variables PV. For example, the first process variable combination COMB_PVa may include process variables PV1a, PV2a, . . . ; the second process variable combination COMB_PVb may include process variables PV1b, PV2b, . . . ; and the third process variable combination COMB_PVc may include process variables PV1c, PV2c, . . . . The process variables included in each of the plurality of process variable combination COMB_PV may correspond to each other. For example, each of the process variables PV1a, PV1b, PV1c may be a process variable corresponding to the first process equipment PE1, and each of the process variables PV2a, PV2b, PV2c may be a process variable corresponding to the second process equipment PE2. However, the scope of the present disclosure is not limited thereto.

A dimension of the process variable combination space SPACE_COMB_PV may be determined based on a number of elements in each of a plurality of process variable combinations COMB_PV. For example, if each of the plurality of process variable combinations COMB_PV includes ‘p’ process variables, the process variable combination space SPACE_COMB_PV may be determined as a ‘p’-dimensional space.

In an embodiment, the process variable combination space SPACE_COMB_PV may be determined in advance by considering correlations between a plurality of process variables PVs. For example, the process variable combination space SPACE_COMB_PV may be implemented to include only points PT corresponding to process variable combinations COMB_PV applicable to the process system 100. In other words, the process variable combination space SPACE_COMB_PV may not include points PT corresponding to process variable combinations COMB_PV that are non-applicable to the process system 100.

The process simulation module 12 may generate a plurality of simulation data SIM based on each of a plurality of process variable combinations COMB_PV provided from the process variable combination generation module 11. For example, the process simulation module 12 may generate first simulation data SIMa based on the first process variable combination COMB_PVa, may generate second simulation data SIMb based on the second process variable combination COMB_PVb, and may generate third simulation data SIMc based on the third process variable combination COMB_PVc.

Each of the plurality of simulation data SIM may correspond to a different combination of virtually measured correlated parameter values COMB_VMV_CR. For example, the virtual measuring module 13 may generate first to third combinations of virtually measured correlated parameter values COMB_VMV_CRa to COMB_VMV_CRc based on the first to third simulation data SIMa to SIMc, respectively.

The plurality of combinations of virtually measured correlated parameter values COMB_VMV_CR may correspond to different points PT within a virtually measured correlated parameter value combination space SPACE_COMB_VMV_CR. For example, the first to third combinations of virtually measured correlated parameter values COMB_VMV_CRa to COMB_VMV_CRc may correspond to fourth to sixth points PT4 to PT6 within the virtually measured correlated parameter value combination space SPACE_COMB_VMV_CR, respectively.

Each of the plurality of combinations of virtually measured correlated parameter values COMB_VMV_CR may include a plurality of virtually measured correlated parameter values VMV_CR. For example, a first combination of virtually measured correlated parameter values COMB_VMV_CRa may include virtually measured correlated parameter values VMV_CR1a to VMV_CRna; a first combination of virtually measured correlated parameter values COMB_VMV_CRb may include virtually measured correlated parameter values VMV_CR1b to VMV_CRnb; and a third combination of virtually measured correlated parameter values COMB_VMV_CRc may include virtually measured correlated parameter values VMV_CR1c to VMV_CRnc. Each of the virtually measured correlated parameter values VMV_CR included in each of the plurality of combinations of virtually measured correlated parameter values COMB_VMV_CR may correspond to the first to n-th correlated structural parameters SPCR1 to SPCRn, respectively. For example, each of the virtually measured correlated parameter values VMV_CR1a, VMV_CR1b, VMV_CR1c may correspond to a first correlated structural parameter SPCR1, and each of the virtually measured correlated parameter values VMV_CR2a, VMV_CR2b, VMV_CR2c may correspond to a second correlated structural parameter SPCR2. However, the scope of the present disclosure is not limited thereto.

A dimension of the virtually measured correlated parameter value combination space SPACE_COMB_VMV_CR may be determined based on a number of elements in each of a plurality of combinations of virtually measured correlated parameter values COMB_VMV_CR. For example, if each of the plurality of combination of virtually measured correlated parameter values COMB_VMV_CR includes ‘n’ virtually measured correlated parameter values VMV_CR, the virtually measured correlated parameter value combination space SPACE_COMB_VMV_CR may be determined as an ‘n’-dimensional space.

For concise explanation, FIG. 5 is representatively described as an embodiment in which each combination of virtually measured correlated parameter values COMB_VMV_CR includes ‘n’ virtually measured correlated parameter values VMV_CR respectively corresponding to the first to n-th correlated structural parameters SPCR1 to SPCRn, but the scope of the present disclosure is not limited thereto. For example, the number of virtually measured correlated parameter values VMV_CR included in each combination of virtually measured correlated parameter values COMB_VMV_CR may vary depending on the target structural parameter SPTG. For example, if the target structural parameter SPTG is an interval between different points of the physical structure PHY, each combination of virtually measured correlated parameter values COMB_VMV_CR may include virtually measured correlated parameter values corresponding to correlated structural parameters (e.g., fewer or more than ‘n’) other than the first to n-th correlated structural parameters SPCR1 to SPCRn.

In an embodiment, the virtually measured correlated parameter value combination space SPACE_COMB_VMV_CR may be determined by considering a normal range of each of the plurality of virtually measured correlated parameter values VMV_CR. For example, the virtually measured correlated parameter value combination space SPACE_COMB_VMV_CR may be implemented to include only points PT corresponding to a combination of virtually measured correlated parameter values COMB_VMV_CR that are unlikely to cause a structural defect. In other words, the virtually measured correlated parameter value combination space SPACE_COMB_VMV_CR may not include points PTs corresponding to a combination of virtually measured correlated parameter values COMB_VMV_CR that are certain to cause a structural defect.

In an embodiment, the virtually measured correlated parameter value combination space SPACE_COMB_VMV_CR may include a space corresponding to a manufacturing target specification (MTS). For example, the virtually measured correlated parameter value combination space SPACE_COMB_VMV_CR may include points PT corresponding to a combination of virtually measured correlated parameter values COMB_VMV_CR that do not cause a structural defect even if they are out of a range satisfying the MTS. However, the scope of the present disclosure is not limited thereto.

In an embodiment, the process variable combination space

SPACE_COMB_PV may be implemented to include only process variable combinations COMB_PV that are predicted not to cause a structural defect. In other words, the process variable combination space SPACE_COMB_PV may not include points PT corresponding to process variable combinations COMB_PV that are certain to cause a structural defect. For example, the process variable combination space SPACE_COMB_PV may be determined such that points PT in the combination of virtually measured correlated parameter values COMB_VMV_CR respectively corresponding to points PT in the process variable combination space SPACE_COMB_PV are included in the virtually measured correlated parameter value combination space SPACE_COMB_VMV_CR. However, the scope of the present disclosure is not limited thereto.

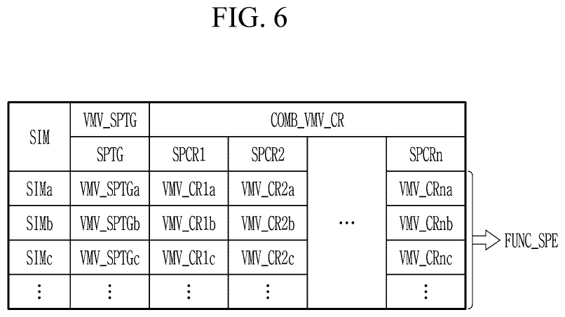

FIG. 6 is a diagram showing the operation of the structural parameter estimation function generation module of FIG. 4. Referring to FIGS. 1 to 6, the structural parameter estimation function generation module 21 may receive, for each of a plurality of simulation data SIM, a virtually measured target structural parameter value VMV_SPTG and a combination of virtually measured correlated parameter values COMB_VMV_CR. For example, the structural parameter estimation function generation module 21 may receive the first virtually measured target structural parameter value VMV_SPTGa and the virtually measured correlated parameter values VMV_CR1a to VMV_CRna corresponding to the first simulation data SIMa; may receive the second virtually measured target structural parameter value VMV_SPTGb and the virtually measured correlated parameter values VMV_CR1b to VMV_CRnb corresponding to the second simulation data SIMb; and may receive the third virtually measured target structural parameter values VMV_SPTGc and the virtually measured correlated parameter values VMV_CR1c to VMV_CRnc corresponding to the third simulation data SIMc.

The structural parameter estimation function generation module 21 may generate a structural parameter estimation function FUNC_SPE corresponding to a target structural parameter SPTG based on the virtually measured target structural parameter values VMV_SPTG and the combinations of virtually measured correlated parameter values COMB_VMV_CR corresponding to the plurality of simulation data SIM.

The structural parameter estimation function FUNC_SPE may be a function that generates an approximate value of the target structural parameter SPTG based on a plurality of correlated structural parameters SPCR corresponding to the target structural parameter SPTG. For example, the structural parameter estimation function FUNC_SPE may be a function that generates an approximate value of the target structural parameter SPTG based on the first to n-th correlated structural parameters SPCR1 to SPCRn. That is, the structural parameter estimation function FUNC_SPE may be defined in the following equation 1.

$$SPTG \approx FUNC\_SPE ( COMB\_CR ) = FUNC\_SPE ( S PCR 1 , S PCR 2 , … , SPCRn ) \qquad [ Equation 1 ]$$

Referring to equation 1, COMB_CR may refer to a combination of sizes of a plurality of correlated structural parameters SPCR, and SPCR1 to SPCRn may refer to sizes of the first to n-th correlated structural parameters SPCR1 to SPCRn, respectively. FUNC_SPE may refer to a structural parameter estimation function FUNC_SPE for the target structural parameter SPTG. SPTG may refer to the size of the target structural parameter SPTG.

The structural parameter estimation function generation module 21 may generate a structural parameter estimation function FUNC_SPE based on a multi-linear regression analysis algorithm. For example, the structural parameter estimation function generation module 21 may generate a structural parameter estimation function FUNC_SPE in a form of the following equation 2.

$$OFST + {\sum }_{k = 1}^{n} ( SPCRk \times COEFk ) \qquad [ Equation 2 ]$$

Referring to equation 2, OFST may refer to an intercept (e.g., offset) of a multi-linear regression function, and SPCRk may refer to an k-th correlated structural parameter SPCRK. COEFk may refer to a regression coefficient corresponding to the k-th correlated structural parameter SPCRk.

The structural parameter estimation function generation module 21 may determine the sizes of OFST and COEF1 to COEFn based on the virtually measured target structural parameter values VMV_SPTG and the combinations of virtually measured correlated parameter values COMB_VMV_CR corresponding to the plurality of simulation data SIM. For example, the structural parameter estimation function generation module 21 may determine the sizes of OFST and COEF1 to COEFn based on residuals of the sizes of target structural parameters SPTG calculated respectively based on the combination of a plurality of virtually measured correlated parameter values COMB_VMV_CR (for example, the residual may refer to a difference between a size of the target structural parameter SPTG calculated by the Equation 2 and a size of the virtually measured target structural parameter value VMV_SPTG). For example, the structural parameter estimation function generation module 21 may determine the sizes of OFST and COEF1 to COEFn so that the sum of squares of the residuals corresponding to each of the plurality of simulation data SIM is minimized. However, the scope of the present disclosure is not limited to the specific manner in which the structural parameter estimation function generation module 21 determines the sizes of OFST and COEF1 to COEFn.

In an embodiment, the structural parameter estimation function generation module 21 may generate a structural parameter estimation function FUNC_SPE using a tobit regression analysis method. That is, the structural parameter estimation function FUNC_SPE may be a tobit function or a tobit model for SPTG. For example, the structural parameter estimation function FUNC_SPE may be defined to have a function value greater than or equal to 0. For example, the structural parameter estimation function FUNC_SPE may be defined based on Equation 2 in a region where the Equation 2 is greater than or equal to ‘0’, and may be defined as ‘0’ in a region where Equation 2 is less than ‘0’. However, the scope of the present disclosure is not limited thereto.

Accordingly, the structural parameter estimation circuit 110 may calculate an approximate value of the target structural parameter SPTG by substituting the first to n-th actually measured correlated parameter values AMV_CR1 to AMV_CRn into SPCR1 to SPCRn of the structural parameter estimation function FUNC_SPE, respectively. That is, the structural parameter estimation circuit 110 may estimate the target structural parameter SPTG based on the structural parameter estimation function FUNC_SPE. Therefore, according to an embodiment of the present disclosure, the structural parameter estimation circuit 110 may estimate the size of a target structural parameter SPTG, which is an unmeasurable structural parameter SP_UMA for a plurality of process stages STG, based on the first to n-th actually measured correlated parameter values AMV_CR1 to AMV_CRn, which are measurable structural parameters SP_MA for the plurality of process stages STG.

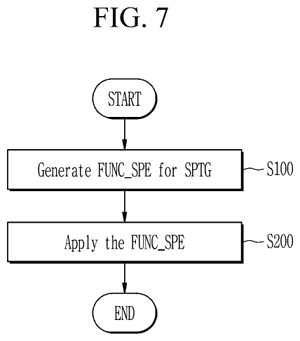

FIG. 7 is a flowchart showing an operation of a correlation analysis system CRAS and a process system according to an embodiment of the present disclosure.

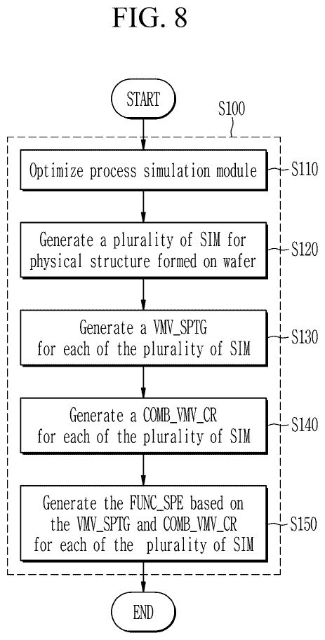

Referring to FIGS. 1 to 7, at operation S100, the correlation analysis system CRAS may generate a structural parameter estimation function FUNC_SPE for the target structural parameter SPTG. The operation S100 is described in more detail with reference to FIG. 8 below.

In an embodiment, the correlation analysis system CRAS may generate a different structural parameter estimation function FUNC_SPE for each of a plurality of target structural parameters different from each other.

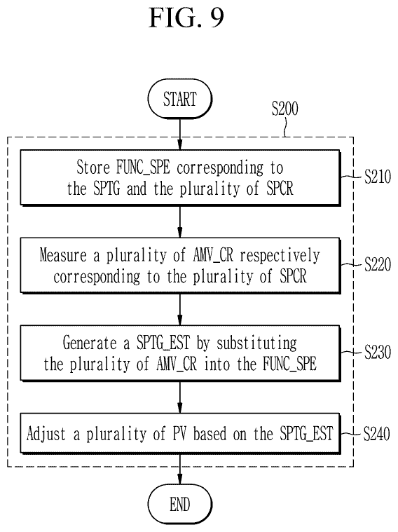

At operation S200, the process system 100 may apply the structural parameter estimation function FUNC_SPE. For example, the process system 100 may estimate target structural parameters SPTG in real time while a plurality of process stages STG are being performed based on the structural parameter estimation function FUNC_SPE generated through operation S100. The operation S200 is described in more detail with reference to FIG. 9 below.

FIG. 8 is a flowchart showing operation S100 of FIG. 7 according to an embodiment of the present disclosure. Referring to FIGS. 1 to 8, operation S100 may include operations S110 to S150 below.

At operation S110, the correlation analysis system CRAS may optimize the process simulation module 12. For example, the correlation analysis system CRAS may optimize the process simulation module 12, such that a simulation data SIM generated based on the process simulation module 12 corresponds to a physical structure PHY generated based on the first to n-th process equipments PE1 to PEn when the process simulation module 12 and the first to n-th process equipments PE1 to PEn operate based on the same process variable combination COMB_PV. That is, the correlation analysis system CRAS may set the process simulation module 12 so as to ensure reliability of simulation data SIM generated by the process simulation module 12.

At operation S120, the correlation analysis system CRAS may generate a plurality of simulation data SIM for the physical structure PHY formed on the wafer WF. For example, the process variable combination generation module 11 may generate a plurality of process variable combinations COMB_PV different from each other. The process simulation module 12 may generate a plurality of simulation data SIM respectively based on of the plurality of process variable combinations COMB_PV different from each other.

At operation S130, the correlation analysis system CRAS may generate a virtually measured target structural parameter value VMV_SPTG for each of the plurality of simulation data SIM. For example, the virtual measuring module 13 may generate a plurality of virtually measured target structural parameter values VMV_SPTG by measuring the target structural parameter SPTG of each of a plurality of simulation data SIM.

At operation S140, the correlation analysis system CRAS may generate a combination of virtually measured correlated parameter values COMB_VMV_CR for each of the plurality of simulation data SIM. For example, the virtual measuring module 13 may generate a plurality of combination of virtually measured correlated parameter values COMB_VMV_CR, by measuring the first to n-th correlated structural parameters SPCR1 to SPCRn for each of the plurality of simulation data SIM.

For concise explanation, an embodiment in which operation S140 is performed after operation S130 is performed is representatively described in FIG. 8, but the scope of the present disclosure is not limited thereto. For example, the correlation analysis system CRAS may perform operations S130 and S140 simultaneously, or may perform operation S130 after operation S140 is performed.

At operation S150, the correlation analysis system CRAS may generate a structural parameter estimation function FUNC_SPE based on the virtually measured target structural parameter value VMV_SPTG and the combination of virtually measured correlated parameter values COMB_VMV_CR for each of the plurality of simulation data SIM. For example, the structural parameter estimation function generation module 21 may generate the structural parameter estimation function FUNC_SPE by performing multi-linear regression analysis for the virtually measured target structural parameter values VMV_SPTG and combinations of virtually measured correlated parameter values COMB_VMV_CR for each of the plurality of simulation data SIM.

In an embodiment, after operation S150 is performed, the correlation analysis system CRAS may provide the structural parameter estimation function FUNC_SPE to the process system 100. In this case, the structural parameter estimation circuit 110 may store the structural parameter estimation function FUNC_SPE.

FIG. 9 is a flowchart showing operation S200 of FIG. 7 according to an embodiment of the present disclosure. Referring to FIGS. 1 to 9, operation S200 may include operations S210 to S240 below.

At operation S210, the process system 100 may store a structural parameter estimation function FUNC_SPE corresponding to a plurality of correlated structural parameters SPCR and a target structural parameters SPTG. For example, the structural parameter estimation circuit 110 may store the structural parameter estimation function FUNC_SPE provided from the correlation analysis system CRAS.

At operation S220, the process system 100 may generate a plurality of actually measured correlated parameter values AMV_CR respectively corresponding to a plurality of correlated structural parameters SPCR. For example, the first to n-th process equipments PE1 to PEn may measure the first to n-th correlated structural parameters SPCR1 to SPCRn while performing the first to n-th process stages STG1 to STGn. In this case, the sizes of the first to n-th correlated structural parameters SPCR1 to SPCRn may be the first to n-th actually measured correlated parameter values AMV_CR1 to AMV_CRn, respectively. The first to n-th process equipments PE1 to PEn may provide the first to n-th actually measured correlated parameter values AMV_CR1 to AMV_CRn to the structural parameter estimation circuit 110.

At operation S230, the process system 100 may generate an estimated target structural parameter value SPTG_EST by substituting the plurality of actually measured correlated parameter values AMV_CR into the structural parameter estimation function FUNC_SPE. For example, the structural parameter estimation circuit 110 may generate an estimated target structural parameter value SPTG_EST by substituting a plurality of actually measured correlated parameter values AMV_CR into the structural parameter estimation function FUNC_SPE. The structural parameter estimation circuit 110 may provide the estimated target structural parameter value SPTG_EST to the process equipment control device 120.

At operation S240, the process system 100 may adjust a plurality of process variables PVs based on the estimated target structural parameter value SPTG_EST. For example, the process equipment control device 120 may identify a risk level of a structural defect which may occur due to the target structural parameter SPTG, based on the estimated target structural parameter value SPTG_EST. The process equipment control device 120 may change the plurality of process variables PVs based on the identified risk level.

FIG. 10 is a block diagram showing the configuration of a correlation analysis system according to an embodiment. Referring to FIGS. 1 to 10, the correlation analysis system CRAS may include a process simulator 10 and a structural parameter estimation function generator 20. The process simulator 10 may include a process variable combination generation module 11, a process simulation module 12, and a virtual measuring module 13. The structural parameter estimation function generator 20 may include a structural parameter estimation function generation module 21 and a correlated structural parameter filtering module 22. The functions of the process variable combination generation module 11, the process simulation module 12, the virtual measuring module 13, and the structural parameter estimation function generation module 21 may be similar to those described above with reference to FIG. 4, and a repetitive description will be omitted.

The process simulation module 12 may generate a plurality of simulation data SIM. The virtual measuring module 13 may generate virtually measured target structural parameter values VMV_SPTG for each of the plurality of simulation data SIM.

The virtual measuring module 13 may measure a plurality of candidate structural parameters SPCDD for each of a plurality of simulation data SIM. In this case, each of the plurality of candidate structural parameters SPCDD may refer to structural parameters SP that are expected to have a correlation with the target structural parameter SPTG.

In an embodiment, the plurality of candidate structural parameters SPCCD may be some of the measurable structural parameters SP_MA for the physical structure PHY. For example, the virtual measuring module 13 may determine some structural parameters that are likely to be correlated with the target structural parameter SPTG among the measurable structural parameters SP_MA for the physical structure PHY as the candidate structural parameters SPCCD based on various types of selection algorithms, such as stepwise selection. However, the scope of the present disclosure is not limited thereto.

The measured value of each of the plurality of candidate structural parameters SPCDD may be referred to as a virtually measured candidate parameter value VMV_CDD. The virtually measured candidate parameter values VMV_CDD measured for each of the plurality of simulation data SIM may be referred to as a combination of virtually measured candidate parameter values COMB_VMV_CDD. For example, the virtual measuring module 13 may generate a first combination of virtually measured candidate parameter values COMB_VMV_CDDa by measuring a plurality of candidate structural parameters SPCDD for the first simulation data SIMa; may generate a second combination of virtually measured candidate parameter values COMB_VMV_CDDb by measuring a plurality of candidate structural parameters SPCDD for the second simulation data SIMb; and may generate a third combination of virtually measured candidate parameter values COMB_VMV_CDDc by measuring a plurality of candidate structural parameters SPCDD for the third simulation data SIMc.

The virtual measuring module 13 may provide a virtually measured target structural parameter values VMV_SPTG and a combination of virtually measured candidate parameter values COMB_VMV_CDD for each of the plurality of simulation data SIM to the structural parameter estimation function generator 20.

The correlated structural parameter filtering module 22 may filter-out the correlated structural parameters SPCR corresponding to the target structural parameter SPTG from among the plurality of candidate structural parameters SPCDD, based on the virtually measured target structural parameter value VMV_SPTG and the combination of virtually measured candidate parameter values COMB_VMV_CDD corresponding to each of the plurality of simulation data SIM. In other words, the correlated structural parameter filtering module 22 may identify whether a structural parameter SP is a correlated structural parameter SPCR for the target structural parameter SPTG based on the virtually measured target structural parameter value VMV_SPTG and the combination of virtually measured candidate parameter values COMB_VMV_CDD corresponding to each of the plurality of simulation data SIM.

In an embodiment, the correlated structural parameter filtering module 22 may notify the identified correlated structural parameters SPCR to the process system 100. For example, the correlated structural parameter filtering module 22 may notify the first to n-th correlated structural parameters SPCR to the process equipment control device 120. In this case, the process equipment control device 120 may change a setup of the first to n-th process equipments PE1 to PEn to measure the first to n-th correlated structural parameters SPCR while performing the first to n-th process stages STG1 to STGn.

The correlated structural parameter filtering module 22 may provide virtually measured candidate parameter values VMV_CDD corresponding to the identified correlated structural parameters SPCR as virtually measured correlated parameter values VMV_CR to the structural parameter estimation function generation module 21.

That is, the virtual measuring module 13 may measure not only a plurality of correlated structural parameters SPCR but also other structural parameters for each of the plurality of simulation data SIM; and the virtual measuring module 13 may generate a combination of virtually measured candidate parameter values COMB_VMV_CDD for each of the plurality of simulation data SIM. In this case, the correlated structural parameter filtering module 22 may provide a part of the combination of virtually measured candidate parameter values COMB_VMV_CDD for each of the plurality of simulation data SIM to the structural parameter estimation function generation module 21 as a combination of virtually measured correlated parameter values COMB_VMV_CR.

In other words, the combination of virtually measured correlated parameter values COMB_VMV_CR for each of the plurality of simulation data SIM may be a subset of combinations of virtually measured candidate parameter values COMB_VMV_CDD for each of the plurality of simulation data SIM. For example, a first combination of virtually measured correlated parameter value COMB_VMV_CRa may be included in the first combination of virtually measured candidate parameter value COMB_VMV_CDDa.

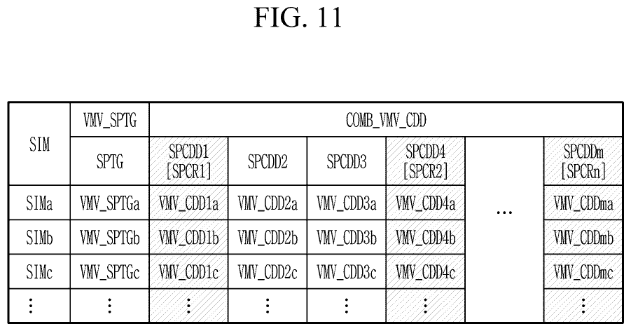

FIG. 11 is a diagram showing an operation of the correlated structural parameter filtering module of FIG. 10 according to an embodiment of the present disclosure. Referring to FIGS. 1 to 11, the correlated structural parameter filtering module 22 may receive a plurality of virtually measured target structural parameter values VMV_SPTG respectively corresponding to the plurality of simulation data SIM. For example, the correlated structural parameter filtering module 22 may receive a virtually measured target structural parameter value VMV_SPTGa corresponding to the first simulation data SIMa; may receive a virtually measured target structural parameter value VMV_SPTGb corresponding to the second simulation data SIMb; and may receive a virtually measured target structural parameter value VMV_SPTGc corresponding to the third simulation data SIMc.

The correlated structural parameter filtering module 22 may receive a plurality of combinations of virtually measured candidate parameter values COMB_VMV_CDD respectively corresponding the plurality of simulation data SIM. Each of the plurality of combinations of virtually measured candidate parameter values COMB_VMV_CDD provided to the correlated structural parameter filtering module 22 may include a plurality of virtually measured candidate parameter values VMV_CDD corresponding to the first to m-th candidate structural parameters SPCDD1 to SPCDDm, respectively. For example, the correlated structural parameter filtering module 22 may receive virtually measured candidate parameter values VMV_CDD1a to VMV_CDDma corresponding to the first simulation data SIMa; may receive virtually measured candidate parameter values VMV_CDD1b to VMV_CDDmb corresponding to the second simulation data SIMb; and may receive virtually measured candidate parameter valuesVMV_CDD1c to VMV_CDDmc corresponding to the third simulation data SIMc.

In an embodiment, a number (e.g., ‘m’) of virtually measured candidate parameter values VMV_CDD included in each of combination of virtually measured candidate parameter value COMB_VMV_CDD may be greater than a number (e.g., ‘n’) of virtually measured correlated parameter values VMV_CR included in each of combination of virtually measured correlated parameter values COMB_VMV_CR.

The correlated structural parameter filtering module 22 may identify some of the plurality of candidate structural parameters SPCDD as correlated structural parameters SPCR for the target structural parameter SPTG, based on the virtually measured target structural parameter values VMV_SPTG and the combinations of virtually measured candidate parameter values COMB_VMV_CDD corresponding to the plurality of simulation data SIM. For example, as illustrated in FIG. 11, the correlated structural parameter filtering module 22 may identify the first candidate structural parameter SPCCD1 as the first correlated structural parameter SPCR1; may identify the fourth candidate structural parameter SPCCD4 as the second correlated structural parameter SPCR2; and may identify the m-th candidate structural parameter SPCCDm as the n-th correlated structural parameter SPCRn, which of each is a part of the first to m-th candidate structural parameters SPCDD1 to SPCDDm.

More specifically, the correlated structural parameter filtering module 22 may compare a determination coefficient or a correlation coefficient of each of the first to m-th candidate structural parameters SPCDD1 to SPCDDm with respect to the target structural parameter SPTG. For example, the correlated structural parameter filtering module 22 may identify candidate structural parameters SPCDD which of each has a determination coefficient for a target structural parameter SPTG higher than a predetermined first threshold value, from among the first to m-th candidate structural parameters SPCDD1 to SPCDDm.

In order to prevent multicollinearity for the structural parameter estimation function FUNC_SPE having a multi-linear regression function form, the correlated structural parameter filtering module 22 may determine only some of the candidate structural parameters SPCDD, whose determination coefficient for the target structural parameter SPTG is higher than the predetermined first threshold value, as the correlated structural parameter SPCR for the target structural parameter SPTG. For example, the correlated structural parameter filtering module 22 may perform a duplicate removal operation on candidate structural parameters SPCDD, which of each has a determination coefficient for the target structural parameter SPTG is higher than the first threshold value and has a correlation level with respect to each other (e.g., a determination coefficient or correlation coefficient for each other) is higher than a second threshold value. For example, if the correlations among the first to third candidate structural parameters SPCDD1 to SPCDD3 with respect to each other are higher than the second threshold value, the correlated structural parameter filtering module 22 may determine only one of the first to third candidate structural parameters SPCDD1 to SPCDD3 (for example, only the first candidate structural parameter SPCDD1) as the correlated structural parameter SPCR for the target structural parameter SPTG.

In this way, the correlated structural parameter filtering module 22 may determine the first to n-th correlated structural parameters SPCR1 to SPCRn.

The correlated structural parameter filtering module 22 may provide a virtually measured target structural parameter values VMV_SPTG corresponding to each of the plurality of simulation data SIM, to the structural parameter estimation function generation module 21.

The correlated structural parameter filtering module 22 may generate a plurality of combinations of virtually measured correlated parameter values COMB_VMV_CR corresponding to a plurality of simulation data SIM, based on combinations of virtually measured candidate parameter values COMB_VMV_CDD corresponding to a plurality of simulation data SIM. The correlated structural parameter filtering module 22 may provide the plurality of combinations of virtually measured correlated parameter values COMB_VMV_CR to the structural parameter estimation function generation module 21. For example, the correlated structural parameter filtering module 22 may provide a combination of virtually measured candidate parameter values VMV_CDD1a, VMV_CDD4a, . . . , VMV_CDDma for the first simulation data SIMa illustrated in shaded regions of FIG. 11 to the structural parameter estimation function generation module 21 as a combination of virtually measured correlated parameter values COMB_VMV_CR for the first simulation data SIMa.

The structural parameter estimation function generation module 21 may generate a structural parameter estimation function FUNC_SPE based on a virtually measured target structural parameter values VMV_SPTG and a combination of virtually measured correlated parameter values COMB_VMV_CR corresponding to each of a plurality of simulation data SIM, similar to that described above with reference to FIG. 4.

That is, according to an embodiment of the present disclosure, the first to n-th correlated structural parameters SPCR1 to SPCRn may be independent of each other (for example, the correlation coefficient or determination coefficient with respect to each other may be low) and may have a high correlation with respect to the target structural parameter SPTG (for example, the correlation coefficient or determination coefficient with respect to the target structural parameter SPTG may be high enough). Therefore, the structural parameter estimation function FUNC_SPE may be able to estimate the structural parameters with high accuracy.

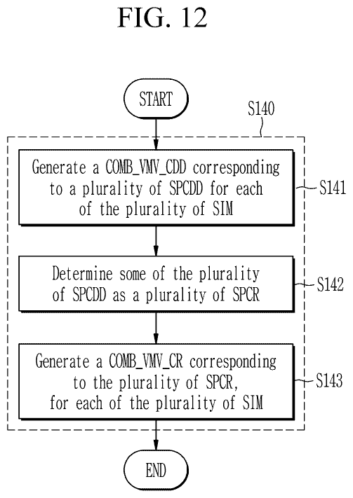

FIG. 12 is a flowchart showing operation S140 of FIG. 8 in more detail according to the embodiments of FIGS. 10 and 11. Referring to FIGS. 1 to 12, operation S140 may include operations S141 to S143 below.

At operation S141, the correlation analysis system CRAS may generate a combination of virtually measured candidate parameter value COMB_VMV_CDD corresponding to a plurality of candidate structural parameters SPCDD for each of a plurality of simulation data SIM. For example, the virtual measuring module 13 may generate a plurality of combinations of virtually measured candidate parameter values COMB_VMV_CDD by measuring the first to m-th candidate structural parameters SPCCD1 to SPCCDm for each of the plurality of simulation data SIM.

At operation S142, the correlation analysis system CRAS may determine some of the plurality of candidate structural parameters SPCDD as the plurality of correlated structural parameters SPCR. For example, the correlated structural parameter filtering module 22 may determine some of the candidate structural parameters SPCDD that have a high correlation with the target structural parameter SPTG as the plurality of correlated structural parameters SPCR. The correlated structural parameter filtering module 22 may determine the plurality of correlated structural parameters SPCR such that each of the plurality of correlated structural parameters SPCR becomes an independent variable to each other.

At operation S143, the correlation analysis system CRAS may generate a combination of virtually measured correlated parameter values COMB_VMV_CR for each of the plurality of simulation data SIM. For example, the correlated structural parameter filtering module 22 may generate a combination of virtually measured correlated parameter values COMB_VMV_CR as a subset of the combination of virtually measured candidate parameter value COMB_VMV_CDD, based on the plurality of correlated structural parameters SPCR.

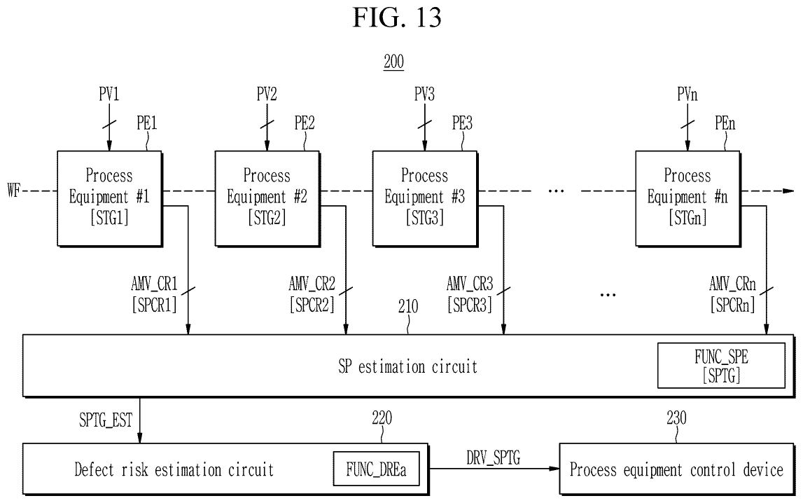

FIG. 13 is a block diagram showing a configuration of a process system according to an embodiment. Referring to FIGS. 1 to 13, a process system 200 may include a plurality of process equipments PE, a structural parameter estimation circuit 210, a defect risk estimation circuit 220, and a process equipment control device 230. The configuration and the operation of the plurality of process equipments PE, the structural parameter estimation circuit 210, and the process equipment control device 230 may be similar to the configuration and the operation of the plurality of process equipments PE, the structural parameter estimation circuit 110, and the process equipment control device 120 described above with reference to FIGS. 1 to 12, and therefore, a repetitive description thereof will be omitted.

The defect risk estimation circuit 220 may receive an estimated target structural parameter value SPTG_EST. The defect risk estimation circuit 220 may store a defect risk estimation function FUNC_DREa. The defect risk estimation circuit 220 may estimate a risk of an occurrence of a structural defect corresponding to a target structural parameter SPTG. For example, the defect risk estimation circuit 220 may generate a target structural parameter defect risk value DRV_SPTG by substituting an estimated target structural parameter value SPTG_EST into the defect risk estimation function FUNC_DREa.

In an embodiment, the defect risk estimation function FUNC_DREa may be defined as one of various types of functions, such as a linear function, a polynomial function, an exponential function, a logarithmic function, etc. However, the scope of the present disclosure is not limited to a specific type of the defect risk estimation function FUNC_DREa.

The defect risk estimation circuit 220 may provide the target structural parameter defect risk value DRV_SPTG to the process equipment control device 230. The process equipment control device 230 may control the plurality of process equipments PE based on the target structural parameter defect risk value DRV_SPTG. For example, the process equipment control device 230 may adjust one or more of the first to n-th process variables PV1 to PVn.

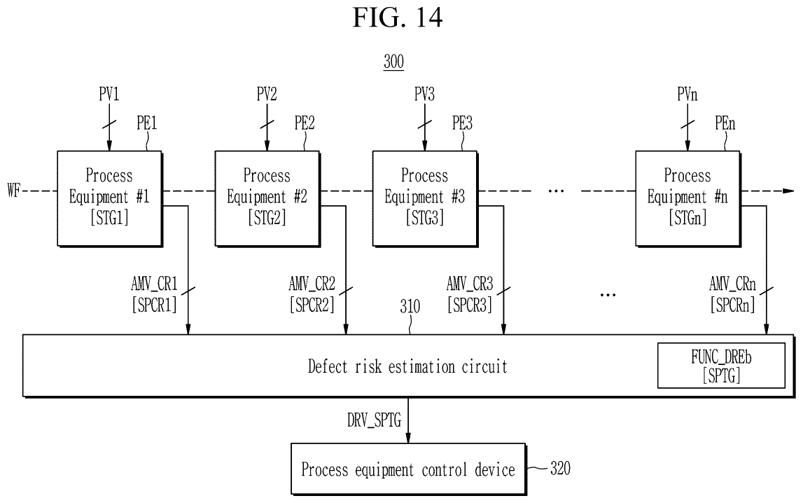

FIG. 14 is a block diagram showing a configuration of a process system according to an embodiment. Referring to FIGS. 1 to 12 and 14, the process system 300 may include a plurality of process equipments PE, a defect risk estimation circuit 310, and a process equipment control device 230. The configuration and the operation of a plurality of process equipments PE may be similar to those that have been described with reference to FIGS. 1 to 12 above, and a detailed description will be omitted.

The defect risk estimation circuit 310 may receive the first to n-th actually measured correlated parameter values AMV_CR1 to AMV_CRn. The defect risk estimation circuit 310 may store a defect risk estimation function FUNC_DREb. The defect risk estimation circuit 310 may estimate a risk of an occurrence of a structural defect corresponding to a target structural parameter SPTG. For example, the defect risk estimation circuit 310 may generate a target structural parameter defect risk value DRV_SPTG by substituting the first to n-th actually measured correlated parameter values AMV_CR1 to AMV_CRn into the defect risk estimation function FUNC_DREb.

The defect risk estimation function FUNC_DREb may have a form of a regression function. For example, the defect risk estimation function FUNC_DREb may be generated based on the correlation analysis system CRAS described above with reference to FIGS. 4 to 6. For example, the correlation analysis system CRAS may generate a defect risk estimation function FUNC_DREb in which the defect risk for a target structural parameter SPTG is expressed in a form of a regression function for a plurality of correlated structural parameters SPCR. Therefore, the defect risk estimation circuit 310 may generate a target structural parameter defect risk value DRV_SPTG by directly substituting the first to n-th actually measured correlated parameter values AMV_CR1 to AMV_CRn into the defect risk estimation function FUNC_DREb.

The process equipment control device 320 may control the plurality of process equipments PE based on the target structural parameter defect risk value DRV_SPTG. For example, the process equipment control device 320 may adjust one or more of the first to n-th process variables PV1 to PVn.

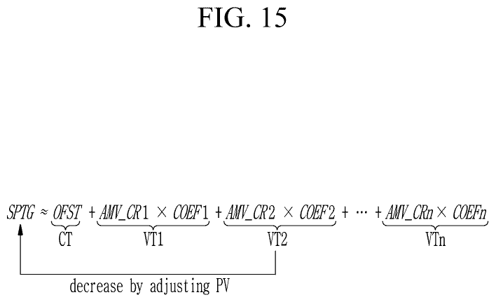

FIG. 15 is a diagram showing an operation of another process system in an embodiment. Referring to FIGS. 1 to 12 and 15, the structural parameter estimation circuit 110 may estimate the size of the target structural parameter SPTG based on the structural parameter estimation function FUNC_SPE. For example, the structural parameter estimation circuit 110 may generate an estimated target structural parameter value SPTG_EST by substituting the first to n-th actually measured correlated parameter values AMV_CR1 to AMV_CRn into the structural parameter estimation function FUNC_SPE.

More specifically, the structural parameter estimation circuit 110 may substitute the first to n-th actually measured correlated parameter values AMV_CR1 to AMV_CRn into the structural parameter estimation function FUNC_SPE. In this case, OFST may be referred to as a constant term CT, and the terms multiplication of the first to n-th actually measured correlated parameter values AMV_CR1 to AMV_CRn and COEF1 to COEFn may be referred to as first to n-th variable terms VT1 to VTn, respectively.

The structural parameter estimation circuit 110 may identify variable terms that have a relatively large influence on the estimated target structural parameter value SPTG_EST by comparing sizes of each of the first to n-th variable terms VT1 to VTn. The structural parameter estimation circuit 110 may notify, to the process equipment control device 120, the variable terms that have a relatively large influence on the estimated target structural parameter value SPTG_EST. For example, the structural parameter estimation circuit 110 may identify that the estimated target structural parameter value SPTG_EST exceeds an appropriate size due to the second variable term VT2. In this case, the structural parameter estimation circuit 110 may notify the process equipment control device 120 to adjust the process variables PV corresponding to the second variable term VT2 to decrease the second variable term VT2. Conversely, the structural parameter estimation circuit 110 may identify that the estimated target structural parameter value SPTG_EST is smaller than the appropriate size due to the second variable term VT2. In this case, the structural parameter estimation circuit 110 may notify the process equipment control device 120 to adjust the process variables PV corresponding to the second variable term VT2 to increase the second variable term VT2.

The process equipment control device 120 may adjust a plurality of process variables PVs in response to a notification from the structural parameter estimation circuit 110. For example, the process equipment control device 120 may adjust the size of one or more process variables PV corresponding to the second variable term VT2. For example, the process equipment control device 120 may adjust the size of one or more process variables PV that are expected to affect a second actually measured correlated parameter value AMV_CR2. In this case, a probability of a structural defect occurring when the process system 100 processes another wafer WF may be reduced. That is, according to the embodiment of the present disclosure, unnecessary control for process variables PV may be reduced, and optimization of the process system 100 may be made easier.

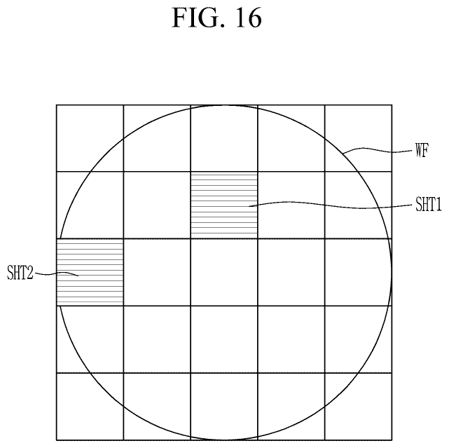

FIG. 16 is a drawing showing the configuration of the wafer of FIG. 1 according to an embodiment. Referring to FIGS. 1 to 12 and 15, a wafer WF may be divided into a plurality of shot regions SHT. The first to n-th process equipments PE1 to PEn may perform the first to n-th process stages STG1 to STGn based on different process variable combinations COMB_PV for each of a plurality of shot regions SHT. For example, the wafer WF may include a first shot region SHT1 and a second shot region SHT2.

The first to n-th process equipments PE1 to PEn may produce same physical structure PHY in each of the plurality of shot regions SHT. For example, the first to n-th process equipments PE1 to PEn may produce same physical structures PHY by performing the first to n-th process stages STG1 to STGn for both of the first shot region SHT1 and the second shot region SHT2. In this case, positions of the physical structures PHY formed in the first shot region SHT1 and the second shot region SHT2 may correspond to each other. For example, a relative position of the physical structure PHY within the first shot region SHT1 may be same as a relative position of the physical structure PHY within the second shot region SHT2. Therefore, the target structural parameter SPTG for the first shot region SHT1 and the target structural parameter SPTG for the second shot region SHT2 may be located at corresponding positions.

The process variable combinations COMB_PV applied for each of the plurality of shot regions SHT may be different from each other. For example, the process variable combination COMB_PV applied when performing the first to n-th process stages STG1 to STGn for the first shot region SHT1 may be different from the process variable combination COMB_PV applied when the first to n-th process equipments PE1 to PEn perform the first to n-th process stages STG1 to STGn for the second shot region SHT2.

The first to n-th process equipments PE1 to PEn may independently generate the first to n-th actually measured correlated parameter values AMV_CR1 to AMV_CRn for each of the plurality of shot regions SHT. For example, the first to n-th process equipments PE1 to PEn may generate actually measured correlated parameter values for a physical structure PHY formed in the first shot region SHT1, and may generate actually measured correlated parameter values for a physical structure PHY formed in the second shot region SHT2.

The structural parameter estimation circuit 110 may estimate both the target structural parameter SPTG for the physical structure PHY formed in the first shot region SHT1 and the target structural parameter SPTG for the physical structure PHY formed in the second shot region SHT2, based on the structural parameter estimation function FUNC_SPE. For example, the structural parameter estimation circuit 110 may estimate the target structural parameter SPTG for the first shot region SHT1 by substituting the actually measured correlated parameter values for the first shot region SHT1 into the structural parameter estimation function FUNC_SPE, and may estimate the target structural parameter SPTG for the second shot region SHT2 by substituting the actually measured correlated parameter values for the second shot region SHT2 into the structural parameter estimation function FUNC_SPE.

That is, according to an embodiment of the present disclosure, a target structural parameter SPTG for each of a plurality of shot regions SHT of a wafer WF may be estimated based on one structural parameter estimation function FUNC_SPE. Therefore, according to the embodiment of the present disclosure, optimization of process variables PVs per shot region SHT may be performed more easily.

At least one of the components, elements, modules or units (collectively “components” in this paragraph) represented by a block in the drawings, may be embodied as various numbers of hardware, software and/or firmware structures that execute respective functions described above, according to one or more example embodiments. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. A process system comprising:
a plurality of process equipments configured to process a wafer based on a plurality of process variables;
a structural parameter estimation circuit configured to generate, based on a first plurality of actually measured correlated parameter values which are provided from the plurality of process equipments and corresponding to a first target structural parameter of the wafer, a first estimated target structural parameter value for the first target structural parameter; and
a process equipment control device configured to control at least one process variable among the plurality of process variables based on the first estimated target structural parameter value.

2. The process system of claim 1, wherein the structural parameter estimation circuit is configured to:
store a structural parameter estimation function; and
generate the first estimated target structural parameter value by substituting the first plurality of actually measured correlated parameter values into the structural parameter estimation function.

3. The process system of claim 2, wherein the structural parameter estimation function is generated based on:
a plurality of simulation data corresponding to physical structures on the wafer, obtained by simulating the plurality of process equipments based on different process variable combinations for the plurality of process variables, respectively.

4. The process system of claim 3, wherein the structural parameter estimation function is generated based on regression analysis for the plurality of simulation data.

5. The process system of claim 4, wherein the structural parameter estimation function is generated based on multi-linear regression analysis for the plurality of simulation data.

6. The process system of claim 2, wherein the structural parameter estimation function is a linear function for each of the first plurality of actually measured correlated parameter values.

7. The process system of claim 2, wherein the structural parameter estimation function is a tobit function for the first target structural parameter.

8. The process system of claim 1, further comprising a defect risk estimation circuit configured to generate a first defect risk value for the first target structural parameter based on the first estimated target structural parameter value,
wherein the process equipment control device is configured to adjust the at least one process variable based on the first defect risk value.

9. The process system of claim 1, wherein the plurality of process equipments are configured to process the wafer by performing a plurality of process stages,
wherein the first plurality of actually measured correlated parameter values are measurable structural parameters for the plurality of process stages, and
wherein the first target structural parameter is an unmeasurable structural parameter for the plurality of process stages.

10. The process system of claim 2, wherein the wafer comprises a first shot region and a second shot region,
wherein the first plurality of actually measured correlated parameter values and the first target structural parameter correspond to the first shot region,
wherein the plurality of process equipments are further configured to provide, to the structural parameter estimation circuit, a second plurality of actually measured correlated parameter values for a second target structural parameter of the second shot region, and
wherein the structural parameter estimation circuit is further configured to generate a second estimated target structural parameter value corresponding to the second target structural parameter by substituting the second plurality of actually measured correlated parameter values into the structural parameter estimation function.

11. The process system of claim 10, wherein a position for the first target structural parameter within the first shot region corresponds to a position for the second target structural parameter within the second shot region, and
wherein positions of structural parameters corresponding to the first plurality of actually measured correlated parameter values correspond to positions of structural parameters corresponding to the second plurality of actually measured correlated parameter values, respectively.

12. An operation method of a correlation analysis system comprising:
generating a plurality of simulation data for a physical structure formed on a wafer;
generating, for each of the plurality of simulation data, a virtually measured target structural parameter value corresponding to a target structural parameter for the physical structure,
generating, for each of the plurality of simulation data, a combination of virtually measured correlated parameter values comprising a plurality of virtually measured correlated parameter values respectively corresponding to a plurality of correlated structural parameters for the target structural parameter; and
generating a structural parameter estimation function based on the combination of virtually measured correlated parameter values and virtually measured target structural parameter values, corresponding to each of the plurality of simulation data.

13. The operation method of claim 12, wherein the generating the combination of virtually measured correlated parameter values comprises:
generating, for each of the plurality of simulation data, a combination of virtually measured candidate parameter values comprising a plurality of virtually measured candidate parameter values respectively corresponding to a plurality of candidate structural parameters for the physical structure;
determining some of the plurality of candidate structural parameters as the plurality of correlated structural parameters, based on the combination of the virtually measured target structural parameter values and the virtually measured candidate parameter values for each of the plurality of simulation data; and
generating, for each of the plurality of simulation data, a combination of virtually measured correlated parameter values corresponding to the plurality of correlated structural parameters.

14. The operation method of claim 12, further comprising:
providing the structural parameter estimation function to a process system which is configured to form the physical structure on the wafer.

15. The operation method of claim 12, wherein the generating the plurality of simulation data comprises:
generating a plurality of different combinations of process variables for a plurality of process stages for forming the physical structure on the wafer; and
generating the plurality of simulation data based on the plurality of different combinations of process variables, respectively.

16. The operation method of claim 12, wherein the generating the structural parameter estimation function comprises:
performing a multi-linear regression analysis based on the combination of virtually measured correlated parameter values and the virtually measured target structural parameter values corresponding to each of the plurality of simulation data.

17. The operation method of claim 12, wherein the target structural parameter is an unmeasurable structural parameter for a plurality of process stages forming the physical structure, and
wherein the plurality of correlated structural parameters are measurable structural parameters for the plurality of process stages.

18. An operation method of a process system for processing a wafer, comprising:
storing a structural parameter estimation function corresponding to a target structural parameter and a plurality of correlated structural parameters of a physical structure formed on the wafer;
generating a plurality of actually measured correlated parameter values respectively corresponding to a plurality of correlated structural parameters, during a plurality of process stages for the wafer;
generating an estimated target structural parameter value for the target structural parameter by substituting the plurality of actually measured correlated parameter values into the structural parameter estimation function; and
adjusting a plurality of process variables provided to the plurality of process equipments based on the estimated target structural parameter value.

19. The operation method of claim 18, wherein the structural parameter estimation function is a multi-linear function for the plurality of correlated structural parameters.

20. The operation method of claim 18, wherein the target structural parameter is an unmeasurable structural parameter for the plurality of process stages, and
wherein the plurality of correlated structural parameters are measurable structural parameters for the plurality of process stages.
